(19) United States
(12) Patent Application Publication
(10) Pub. No.: US 2015/0109731 A1
(43) Pub. Date: Apr. 23, 2015

(54) ELECTRONIC DEVICE

(71) Applicant: Fujitsu Limited, Kawasaki-shi (JP)

(72) Inventors: Misao Umematsu, KAWASAKI (JP); Yoshimi Kadotani, Kawasaki (JP); Keita Hirai, KAWASAKI (JP)

(21) Appl. No.: 14/514,886

(22) Filed: Oct. 15, 2014

(30) Foreign Application Priority Data
Oct. 22, 2013 (JP) 2013-219478

(51) Int. Cl. H05K 7/20

(52) U.S. Cl. CPC H05K 7/20136; H05K 7/2029; H05K 7/20327; H05K 7/20145
USPC 361/691

(57) ABSTRACT

An electronic device includes: an air-cooled substrate on which an air-cooled component that is cooled by an airflow is mounted; a liquid-cooled substrate that is set apart from the air-cooled substrate in plan view, the liquid-cooled substrate being mounted thereon a liquid-cooled component that is cooled by a liquid; and a refrigerant supply member that is disposed above the liquid-cooled substrate, the refrigerant supply member supplying a refrigerant that cools the liquid-cooled component.

### CROSS-REFERENCE TO RELATED APPLICATION

This application is based upon and claims the benefit of priority of the prior Japanese Patent Application No. 2013-219478, filed on Oct. 22, 2013, the entire contents of which are incorporated herein by reference.

### FIELD

The embodiment discussed herein is related to an electronic device.

### BACKGROUND

There is an electronic component cooling device including a water-cooled plate provided on a backside of a substrate and an exhaust-heat cooling heat exchanger provided on a front side of the substrate. Furthermore, there is a mounting structure in which components to be cooled by water are mounted on one surface of a first mounting board and electronic components that may be cooled by air sufficiently are mounted on second mounting boards, the second mounting boards being mounted on the other surface of the first mounting board.

Additionally, there is a structure in which components that may be cooled by air sufficiently are cooled by cold air blown down from an indoor unit of an air-conditioner and in which components to be cooled by liquid are cooled by a coolant.

The following are reference documents.
[Document 1] Japanese Laid-open Patent Publication No. 2012-128710,
[Document 2] Japanese Laid-open Patent Publication No. 63-289999, and
[Document 3] Japanese Laid-open Patent Publication No. 2007-330656.

### SUMMARY

According to an aspect of the invention, an electronic device includes: an air-cooled substrate on which an air-cooled component that is cooled by an airflow is mounted; a liquid-cooled substrate that is set apart from the air-cooled substrate in plan view, the liquid-cooled substrate being mounted thereon a liquid-cooled component that is cooled by a liquid; and a refrigerant supply member that is disposed above the liquid-cooled substrate, the refrigerant supply member supplying a refrigerant that cools the liquid-cooled component.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a plan view illustrating an electronic device of a first exemplary embodiment;

FIG. 2 is a perspective view illustrating the electronic device of the first exemplary embodiment;

FIG. 3 is a perspective view illustrating a state in which a plurality of electronic devices of the first exemplary embodiment is mounted in a rack;

FIG. 4 is a perspective view illustrating a portion of a structure of the electronic device of the first exemplary embodiment;

FIG. 5 is a plan view illustrating a liquid-cooled substrate of the electronic device of the first exemplary embodiment;

FIG. 6 is a plan view illustrating the liquid-cooled substrate of the electronic device of the first exemplary embodiment;

FIG. 7A is a plan view illustrating the electronic device of the first exemplary embodiment;

FIG. 7B is a cross-sectional view taken along line 7B-7B′ of FIG. 7A illustrating the electronic device of the first exemplary embodiment;

FIG. 8 is a cross-sectional view taken along line 8-8 of FIG. 5;

FIG. 9 is a front view illustrating a state in which an intermediate substrate and each of the liquid-cooled substrates of the electronic device of the first exemplary embodiment are connected to each other;

FIG. 10 is a plan view illustrating an electric connection member of the electronic device of the first exemplary embodiment;

FIG. 11A is a block diagram illustrating a state in which electric power is supplied to the electronic device of the first exemplary embodiment;

FIG. 11B is a block diagram illustrating a state in which electric power is supplied to the electronic device of the first exemplary embodiment;

FIG. 12 is a perspective view illustrating a state in which the intermediate substrate and each of the liquid-cooled substrates of the electronic device of the first exemplary embodiment are connected to each other; and

FIG. 13 is a perspective view illustrating a state in which an intermediate substrate and liquid-cooled substrates of an electronic device of a comparative example are connected to one another.

### DESCRIPTION OF EMBODIMENT

A first exemplary embodiment will be described in detail with reference to the drawings.

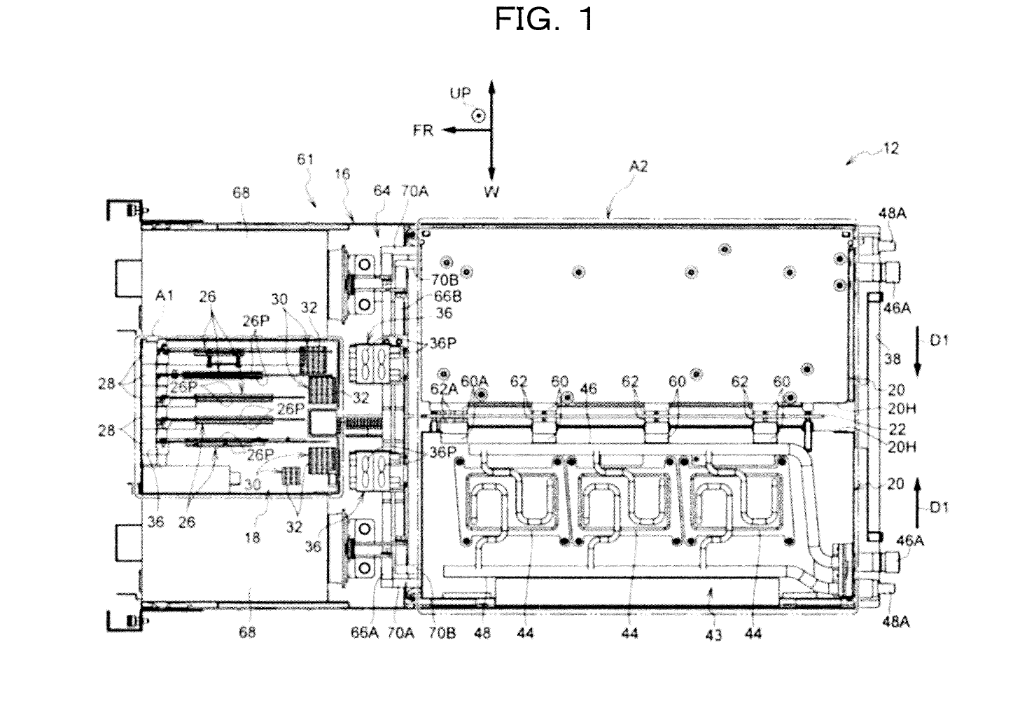

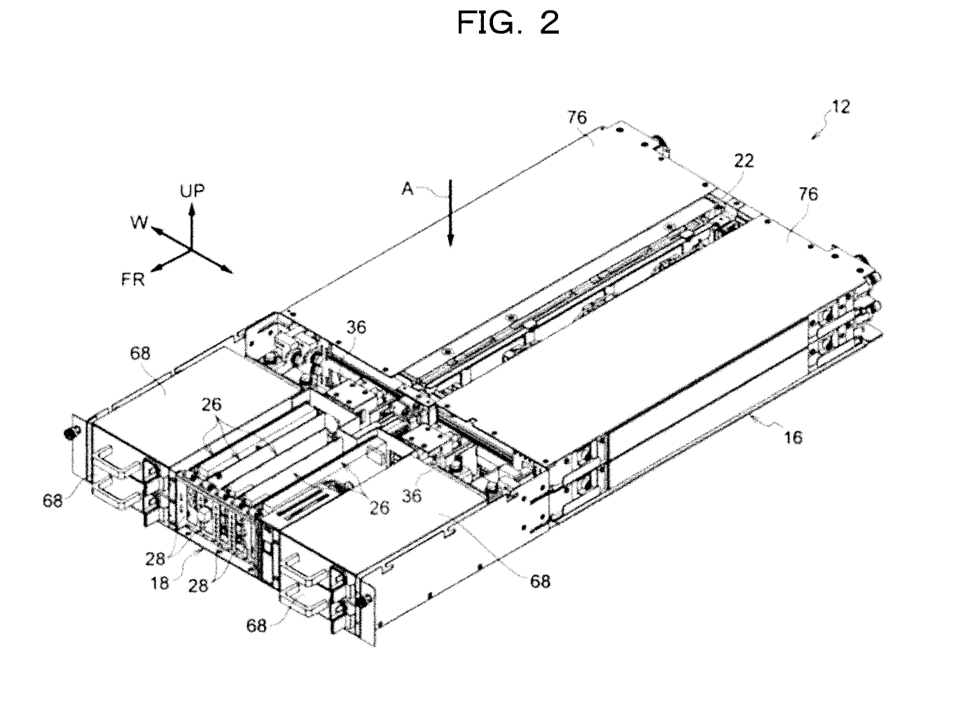

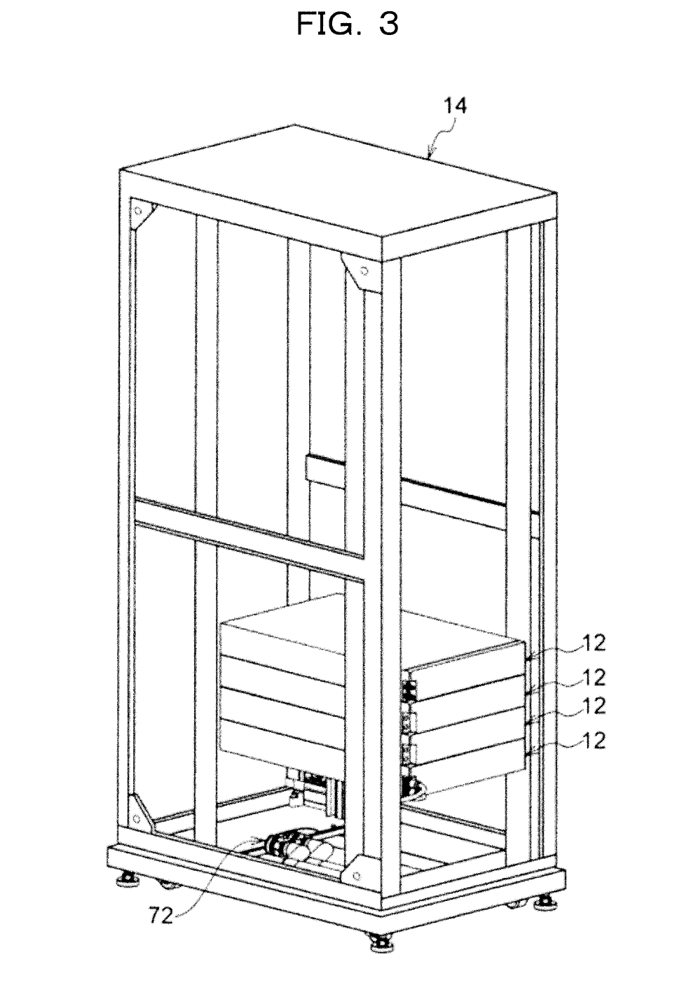

FIGS. 1 and 2 each illustrate an electronic device 12 of the first exemplary embodiment. Furthermore, FIG. 3 illustrates a structure in which a plurality of (not limited to four as illustrated in FIG. 3) electronic devices 12 are mounted in a rack 14. Hereinafter, in the drawings, the front direction, the width direction, and the upper direction of the electronic device 12 will be depicted by arrows FR, W, and UP, respectively. The directions are for convenience of description and do not restrict the actual directions of the installed electronic device 12. Furthermore, when “in plan view” is merely used, it will mean to view the electronic device 12 from the upper side towards the lower side of the electronic device 12 in the height direction (the direction of arrow A).

The electronic device 12 includes a housing 16 formed in a rectangular frame shape in plan view. An air-cooled substrate 18 is disposed on the near side of the housing 16 (on the side of the housing 16 in the arrow FR direction) and at the middle portion of the housing 16 in the width direction. Furthermore, a plurality of (four in total, two in the width direction and two in the height direction, in the example illustrated in FIG. 1) power units 68 are disposed on the front side of the housing 16 and at the left and right of the air-cooled substrate 18 in the width direction.

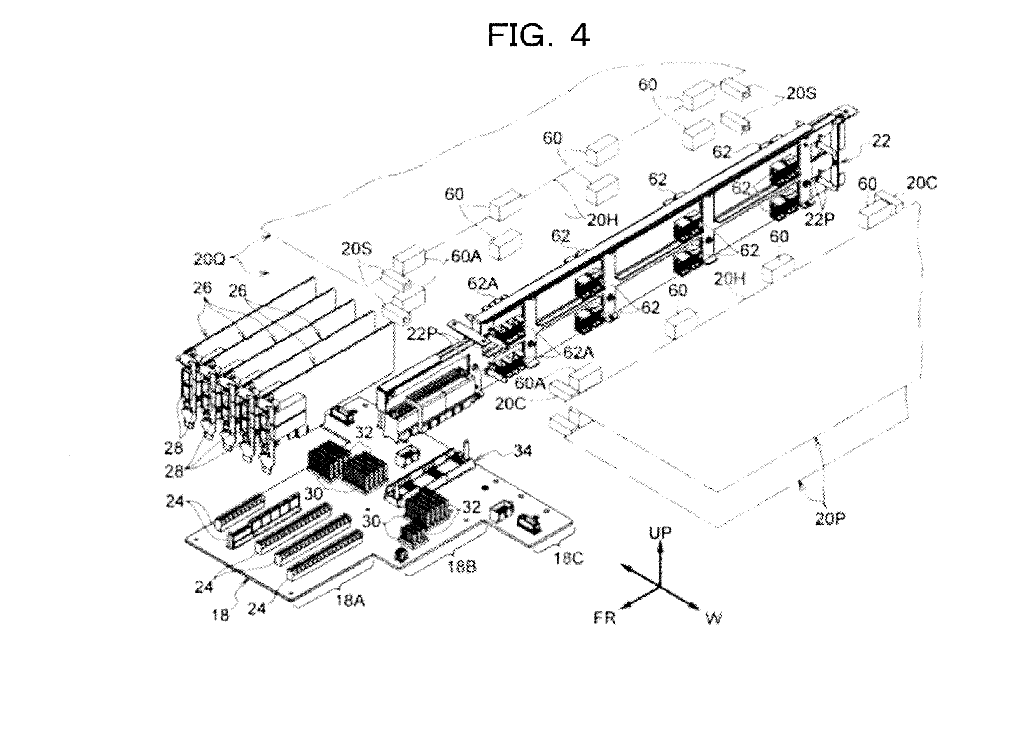

As illustrated in FIG. 4, inside the housing 16, a plurality of (four in total, two in the width direction and two in the height direction, in the example illustrated in FIG. 4) liquid-cooled substrates 20 are disposed on the far side of the housing 16 (on the side of the housing 16 in a direction countering the arrow FR) with respect to the air-cooled substrate 18. An intermediate substrate 22 is disposed between the liquid-cooled substrates 20 that are aligned in the width direction. The intermediate substrate 22 electrically connects the plurality of liquid-cooled substrates 20 to one another. Note that FIG. 2 illustrates a state in which cover plates 76 are disposed on the liquid-cooled substrates 20.

As illustrated in detail in FIG. 4, the air-cooled substrate 18 includes, from the front side in the following order, a narrow-width portion 18A, an intermediate portion 18B, and a wide-width portion 18C. The width of the wide-width portion 18C is wider than that of the narrow-width portion 18A, and the width of the intermediate portion 18B is between the widths of the narrow-width portion 18A and the wide-width portion 18C.

Card connectors 24 are attached to the narrow-width portion 18A. Connection cards 26 are connected to the air-cooled substrate 18 through the card connectors 24. In the example illustrated in FIG. 4, five connection cards 26 are each arranged perpendicular to the air-cooled substrate 18 and in the front-rear direction such that the five connection cards 26 stand erect with a space between one another in the width direction. Each of the connection cards 26 includes a connection port 28 for an external device. An external device may be connected to the connection port 28 directly or through a connection cable or the like. The connection cards 26 are each an example of a connection member. Electronic components 26P are mounted on the connection cards 26.

In the exemplary embodiment, each connection card 26 is disposed so that the connection port 28 faces the front direction. When external devices are connected to the connection ports 28, the liquid-cooled substrates 20 and liquid-cooled components 40 and the like on the liquid-cooled substrates 20 that will described later will not be in the way.

Air-cooled components 30 are mounted on the intermediate portion 18B of the air-cooled substrate 18. Heat sinks 32 are attached on the air-cooled components 30. Heat of the air-cooled components 30 is conducted to the heat sinks 32. Then, the heat sinks 32 are cooled by the air flowing over the air-cooled substrate 18 and, accordingly, the air-cooled components 30 are cooled as well. An integrated circuit may be cited as an example of the air-cooled component 30. Note that if the flow of air is capable of directly cooling the air-cooled components 30, the heat sinks 32 may be omitted.

An intermediate substrate connector 34 is attached to a portion of the air-cooled substrate 18 from the wide-width portion 18C to the intermediate portion 18B. The intermediate substrate 22 is electrically connected to the air-cooled substrate 18 through the intermediate substrate connector 34. The intermediate substrate 22 not only electrically connects the plurality of liquid-cooled substrates 20 to one another but also electrically connects each of the liquid-cooled substrates 20 to the air-cooled substrate 18.

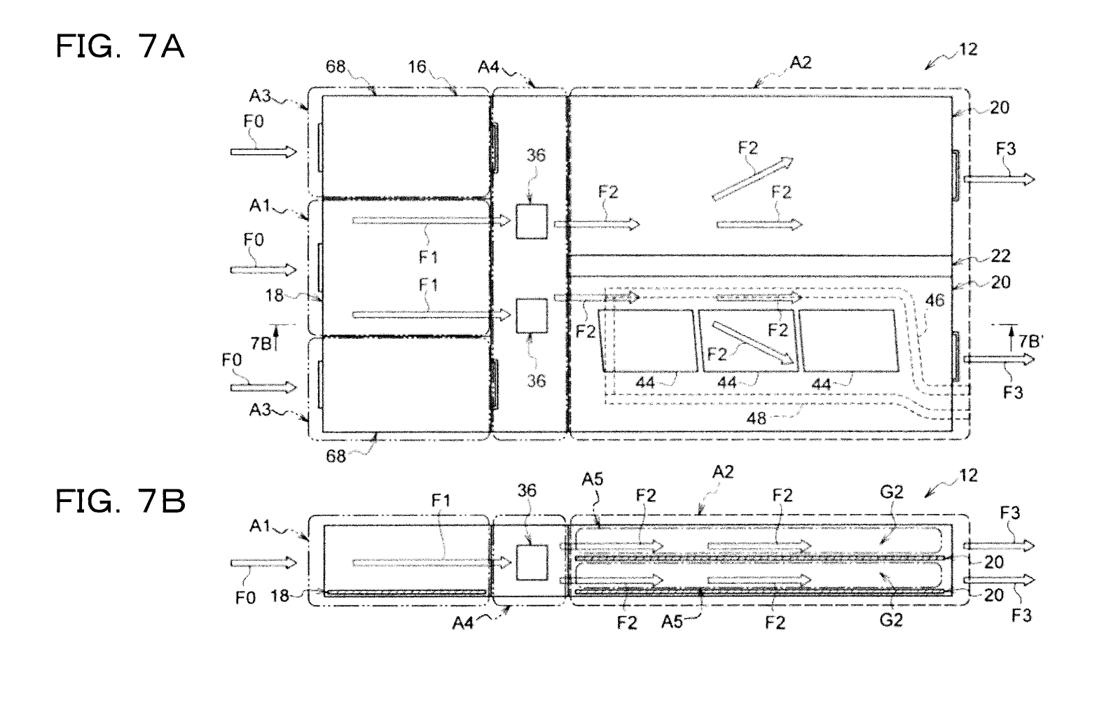

Fans 36 are disposed on the wide-width portion 18C of the air-cooled substrate 18 at a position near the liquid-cooled substrates 20. In each of the examples illustrated in FIGS. 1 and 2, two fans 36 are arranged so as to be spaced apart from each other in the width direction. The fans 36 are driven so that air is introduced through introduction ports 16A of the housing 16 (see introduced air F0 illustrated in FIGS. 7A and 7B). In the housing 16, introduced air F1 upstream of the fans 36 flows over the air-cooled substrate 18 and cools the air-cooled components 30. Furthermore, the introduced air F1 also cools the connection cards 26 and the electronic components 26P mounted on the connection cards 26. Discharged air F2 downstream of the fans 36 flows over the liquid-cooled substrates 20. Then, the air is discharged to the outside of the housing 16 through the discharge ports 38 as discharged air F3.

By disposing the fans 36 on the air-cooled substrate 18 and near the liquid-cooled substrates 20, that is, by disposing the fans 36 on the rear side (the far side), the card connectors 24 may be disposed on the near side. Regarding the blowing capacity of the fans 36, since the fans 36 only have to cool the air-cooled components 30 that are mounted on the air-cooled substrate 18, the size of the fans 36 may be reduced compared with a structure in which components other than the air-cooled components 30 are cooled.

As illustrated in FIG. 1, the fans 36 each include a plurality of (two in the example of FIG. 1) fan bodies 36P that are arranged in the flow direction of the airflow. The fan bodies 36P may each individually generate an airflow. The fans 36 include the plurality of fan bodies 36P that are arranged in the flow direction of the airflow such that redundancy is provided.

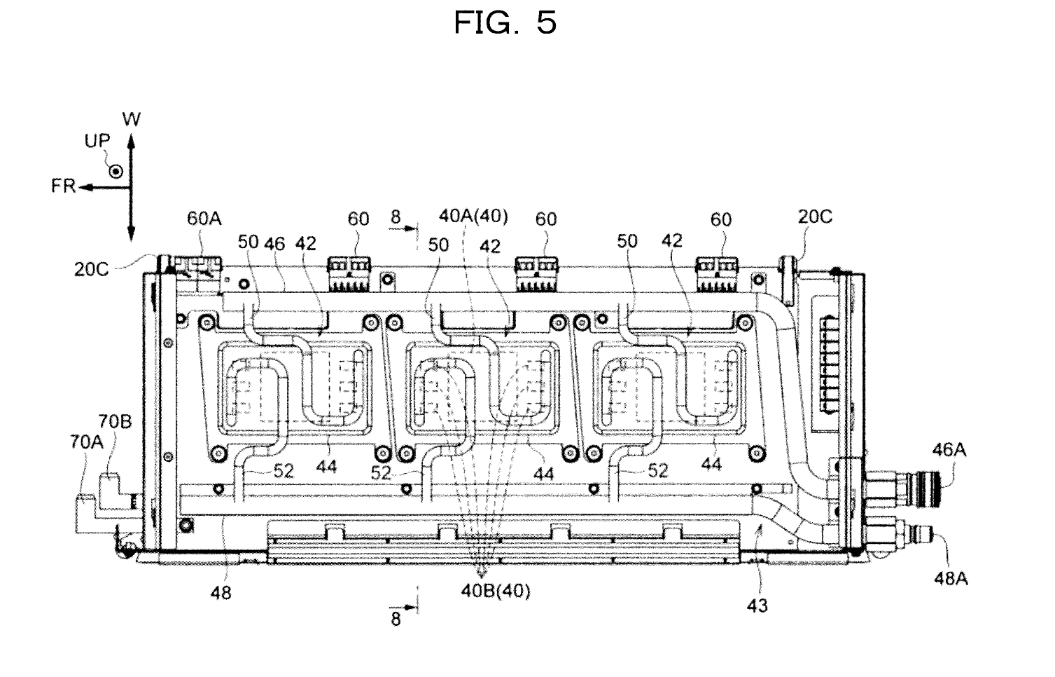

As illustrated in FIG. 5 as well, one or more liquid-cooled components 40 are mounted on each of the liquid-cooled substrates 20. An integrated circuit may be cited as an example of the liquid-cooled component 40. In the example illustrated in FIG. 5, three units 42 subject to cooling in which a plurality of (six in the example illustrated in FIG. 5) memories 40B are arranged in the vicinity of a single processor 40A are disposed in a single liquid-cooled substrate 20. In the exemplary embodiment, since the electronic device 12 includes four liquid-cooled substrates 20, the electronic device 12 as a whole has a total of 12 units 42 subject to cooling (processor 40A).

The liquid-cooled components 40 are cooled by a refrigerant supplied from a refrigerant supply member 43. In the exemplary embodiment, although water is used as the refrigerant, the refrigerant may be a liquid other than water.

The refrigerant supply member 43 includes liquid-cooled plates 44 arranged over the units 42 subject to cooling, an introduction pipe 46, a discharge pipe 48, branched introduction pipes 50, and branched discharge pipes 52.

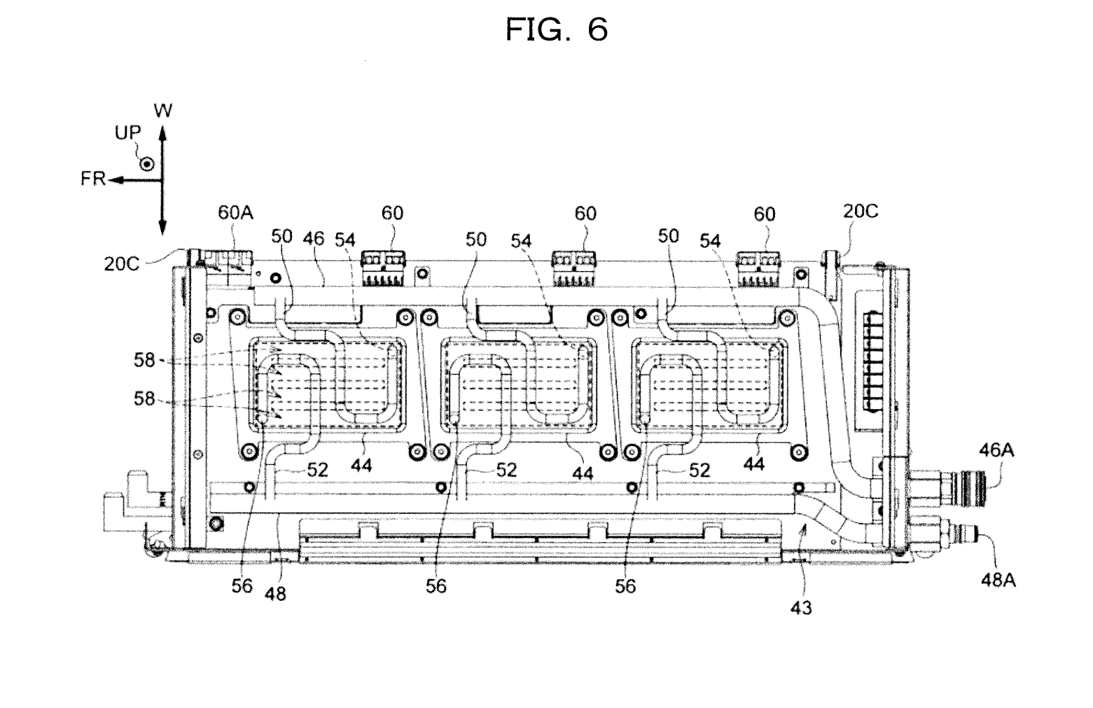

As described in detail in FIGS. 5 and 6, the liquid-cooled substrate 20 is provided with the introduction pipe 46 into which cooling water is introduced and a discharge pipe 48 from which the cooling water is discharged. One end of the introduction pipe 46 is an introduction port 46A through which the cooling water sent from a refrigerant supply device 72 illustrated in FIG. 3 is introduced. One end of the discharge pipe 48 is a discharge port 48A from which the cooling water is returned to the refrigerant supply device 72. In the exemplary embodiment, the introduction port 46A and the discharge port 48A are both arranged so as to face the rear direction.

The branched introduction pipes 50 are branched off from the introduction pipe 46 towards the liquid-cooled plates 44 and the branched discharge pipes 52 are branched off from the discharge pipe 48 towards the liquid-cooled plates 44. The cooling water sent from the refrigerant supply device 72 is branched from the introduction pipe 46 into the branched introduction pipes 50, flows inside the liquid-cooled plate 44, then, passes through the discharge pipe 48 from the branched discharge pipes 52, and returns to the refrigerant supply device 72.

As illustrated in detail in FIG. 6, a liquid inlet 54 and a liquid outlet 56 is formed in each liquid-cooled plate 44. In the example illustrated in FIG. 6, each liquid-cooled plate 44 has a rectangular shape in plan view and the liquid inlet 54 and the liquid outlet 56 are formed diagonal to each other.

A plurality of liquid passages 58 that extend along the long sides of the liquid-cooled plate 44 are formed inside the liquid-cooled plate 44. The refrigerant that has entered the liquid-cooled plate 44 through the liquid inlet 54 is separated and flows through the plurality of liquid passages 58 and flows out from the liquid outlet 56 to the branched discharge pipe 52. When the refrigerant flows inside the liquid-cooled plate 44, the heat of the liquid-cooled components 40 is transmitted to the refrigerant and the liquid-cooled components 40 are cooled.

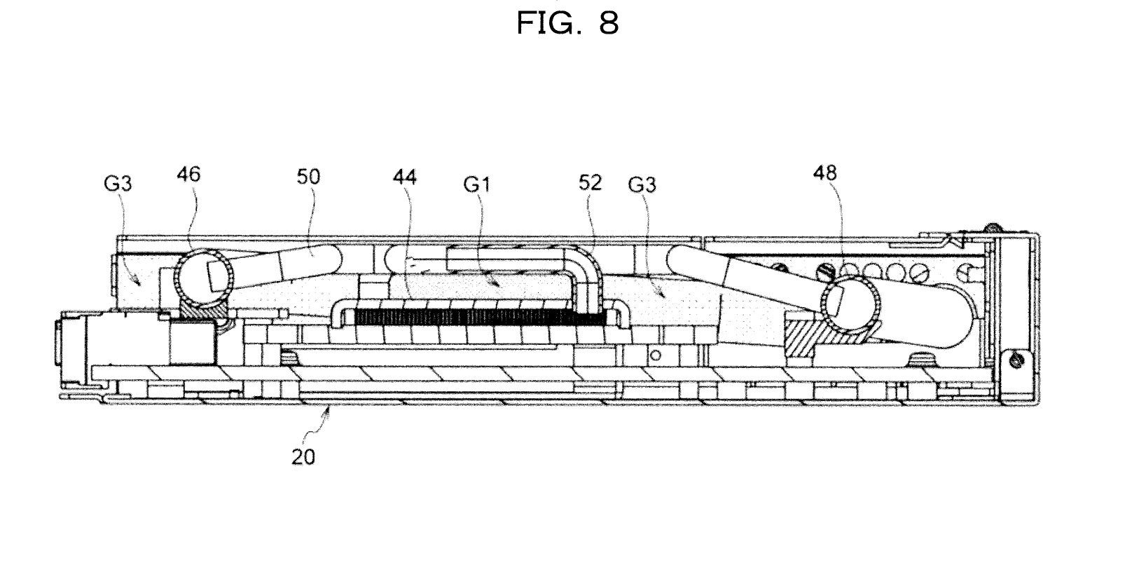

As illustrated in FIG. 8 as well, the introduction pipe 46, the branched introduction pipes 50, the branched discharge pipes 52, and the discharge pipe 48 are formed in a thin manner such that an amount of refrigerant sufficient to cool the liquid-cooled components 40 is allowed to flow therethrough; accordingly the resistance met by the flow of air is small.

The outside diameter and the height of a portion of the introduction pipe 46 that extends in the flow direction of the air (discharged air) are uniform in the flow direction of the air. Accordingly, compared with a structure in which the outer diameter or the height of the introduction pipe 46 changes in the direction of the airflow, the area occupied by the introduction pipe 46 in the direction of the airflow is small and, thus, the resistance met by the airflow is small. Furthermore, the outside diameter and the height of a portion of the discharge pipe 48 that extends in the flow direction of the air (discharged air) are uniform in the flow direction of the air. Accordingly, compared with a structure in which the outer diameter or the height of the discharge pipe 48 changes in the direction of the airflow, the area occupied by the discharge pipe 48 in the flow direction of the discharged air is small and, thus, the resistance met by the airflow is small.

The outside diameter and the height of each branched introduction pipe 50 and the outside diameter and the height of each branched discharge pipe 52 are the same. Accordingly, compared with a structure in which the outer diameters and the heights of the branched introduction pipes 50 and the branched discharge pipes 52 are not the same, the areas occupied by the branched introduction pipes 50 and the branched discharge pipes 52 in the flow direction of the discharged air are small and, thus, the resistance met by the flow of the discharged air is small.

As seen in FIGS. 5 and 6, a portion of each branched introduction pipe 50 and a portion of each branched discharge pipe 52 are positioned over a corresponding liquid-cooled plate 44. Moreover, as illustrated in FIG. 8, the heights (positions) of the branched introduction pipes 50 and the heights (positions) of the branched discharge pipes 52 are set such that gaps G1 are formed between the liquid-cooled plate 44 and each of the branched introduction pipe 50 and branched discharge pipe 52. The gap G1 is an example of an air passage.

Furthermore, gaps G3 are formed above the liquid-cooled substrate 20 in the airflow direction. The gap G3 is also an example of the air passage. In other words, the gaps G1 and the gaps G3 are formed so as not to impede the airflow or are formed such that the resistance met by the flow is small.

In particular, when viewed in the airflow direction, the gaps G1 are arranged at the same position above the plurality of (three in the example of FIG. 1) liquid-cooled plates 44 in a single liquid-cooled substrate 20 and, as a result, a linear flow of air or a flow of air that is close to a straight line is created; accordingly, the structure is one that does not impede the airflow.

As illustrated in FIGS. 1 and 4 to 6, one or more signal connectors 60 and a signal connector 60A are provided on one side 20H of each liquid-cooled substrate 20. Conversely, connection connectors 62 and 62A are provided in the intermediate substrate 22 in a one-to-one manner with the signal connectors 60 and 60A. By connecting the signal connectors 60 and 60A with the connection connector 62 and 62A, respectively, the liquid-cooled substrate 20 becomes electrically connected to the intermediate substrate 22. In the example illustrated in FIGS. 1 and 4, the signal connectors 60 and the connection connectors 62 are each associated with a processor 40A. Conversely, the signal connector 60A and the connection connector 62A are connectors to further connect the liquid-cooled substrate 20 to another member (the air-cooled substrate 18, for example) through the intermediate substrate 22.

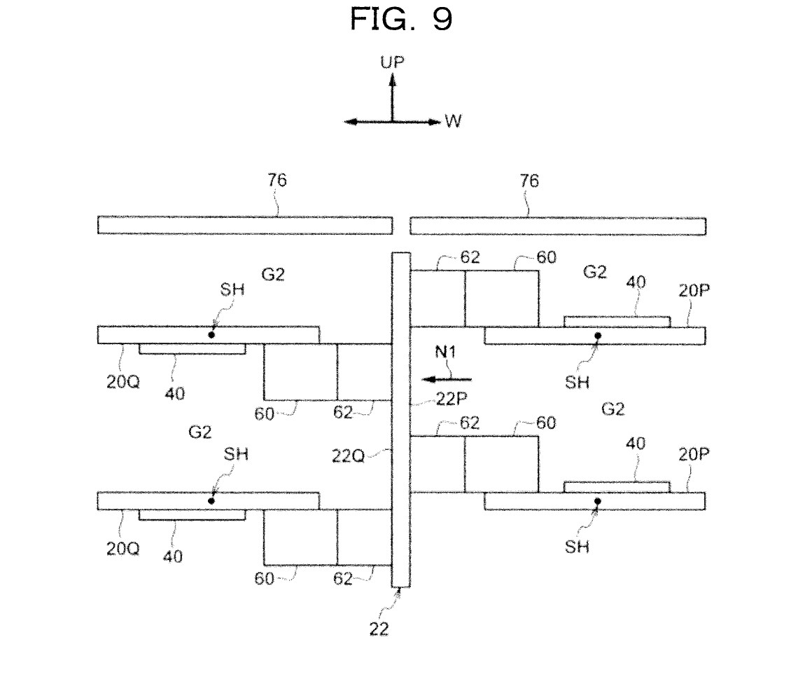

As seen in FIG. 9, the liquid-cooled substrates on one side of the electronic device 12 in the width direction (liquid-cooled substrates 20P on one side) and the liquid-cooled substrates on the other side of the electronic device 12 in the width direction (liquid-cooled substrates 20Q on the other side) are connected to the intermediate substrate 22 such that the liquid-cooled substrates 20P on one side and the liquid-cooled substrates 20Q on the other side are, with respect to one another, arranged at inverted positions that are inverted about axes SH extending in the longitudinal direction of the electronic device 12. Note that the relationship between the liquid-cooled substrates 20P on one side and the liquid-cooled substrates 20Q on the other side are relative. Accordingly, the liquid-cooled substrates 20Q may be referred to as the liquid-cooled substrates on one side and the liquid-cooled substrates 20P may be referred to as the liquid-cooled substrates on the other side.

Since the signal connectors 60 are provided on the liquid-cooled substrates 20, if the liquid-cooled substrates 20P and the liquid-cooled substrates 20Q are connected to the intermediate substrate 22 at the same height, then the height of the signal connectors 60 on the liquid-cooled substrate 20P side and the height of the signal connectors 60 on the liquid-cooled substrate 20Q side will differ. In response to the above, the connection connectors 62 on one surface 22P of the intermediate substrate 22 and the connection connectors 62 on the other surface 22Q of the intermediate substrate 22 are set at different heights when viewed from a direction normal to the intermediate substrate 22 (in the direction of arrow N1).

One or more (two spaced apart in the front-rear direction in the examples illustrated in FIGS. 5 and 6) receiving tubes 20C are provided on the one side 20H of the liquid-cooled substrate 20. Positioning pins 22P that are received into the receiving tubes 20C are provided on the intermediate substrate 22. The liquid-cooled substrates 20 are slid in either one of the directions of arrows D1 illustrated in FIG. 1 to be connected to the intermediate substrate 22. When a liquid-cooled substrate 20 is connected to the intermediate substrate 22, the positioning pins 22P are received in the receiving tube 20C such that the position of the liquid-cooled substrate 20 is determined with respect to the intermediate substrate 22.

The intermediate substrate 22 is disposed inside the housing 16 in the airflow direction (in the direction of arrow F1 and arrow F2). In particular, in the example illustrated in FIG. 1, when viewed in the airflow direction, the intermediate substrate 22 is disposed in the middle of the width direction and perpendicular to the air-cooled substrate 18. When viewed in the flow direction of the cooling water, the intermediate substrate 22 is positioned between the two fans 36 such that the streams of discharged air from the fans 36 are restrained from being mixed together; accordingly, the streams of discharged air are guided along the intermediate substrate 22 towards the air discharge ports 38.

As illustrated in FIG. 9, when viewed in the airflow direction, two liquid-cooled substrates 20 are disposed on each of the two sides of the intermediate substrate 22; accordingly, a gap G2 is formed between each of the two upper and lower liquid-cooled substrates 20 and between each of the most upper liquid-cooled substrates 20 and the cover plate 76. The gap G2 is also an example of the air passage.

Furthermore, a memory that may be mounted directly on the substrate, for example, may be used as the memory 40B on the liquid-cooled substrate 20. Reducing the height of the memory 40B allows a high air passage to be obtained. Furthermore, since the total height of the liquid-cooled substrate 20 and the liquid-cooled components 40 may be reduced, contribution to high density mounting of the liquid-cooled substrates 20 in the electronic device 12 may be made.

Electric power is supplied to the air-cooled substrate 18 and the liquid-cooled substrates 20 from a power supply member 61. The power supply member 61 includes the power units 68 and a busbar unit 64. The busbar unit 64 is an example of an electric connection member. A signal indicating a driving state of each power unit 68 is sent to a control circuit, and the control circuit controls each power unit 68 based on the signal.

As illustrated in FIGS. 1 and 2, the busbar unit 64 is disposed on the front side with respect to the liquid-cooled substrates 20, in other words, the busbar unit 64 is positioned between the liquid-cooled substrates 20 and the power units 68. The busbar unit 64 includes two busbars 66A and 66B extending in the width direction. One busbar, that is, the busbar 66A, is connected to high potential sides of the four power units 68, and the other busbar, that is, the busbar 66B is connected to low potential sides of the four power units 68. Accordingly, a potential difference is induced across the busbar 66A and the busbar 66B.

As illustrated in FIGS. 5 and 6, each liquid-cooled substrate 20 is provided with two power terminals 70A and 70B. While each of the liquid-cooled substrates 20 is attached to a predetermined position in the housing 16, the electric terminals 70A and 70B of each of the liquid-cooled substrates 20 are connected to the electric terminals 67A and 67B of the busbars 66A and 66B, respectively such that power is supplied to each of the liquid-cooled substrates 20.

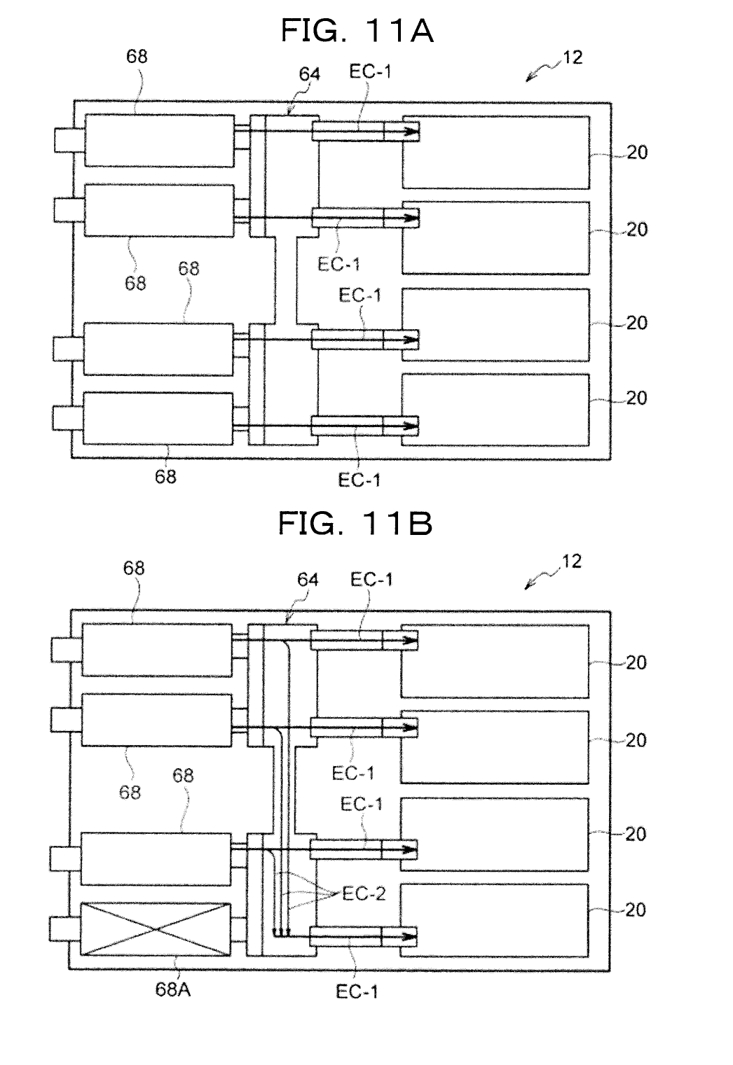

In the exemplary embodiment, the four power units 68 are all connected to the busbars 66A and 66B. As illustrated by arrows EC-1 in FIG. 11A, when the four power units 68 are driven, electric power may be supplied from each of the four power units 68 to the corresponding liquid-cooled substrate 20.

As illustrated in FIG. 11B, an example in which one of the power units 68 (a power unit 68A in the example of FIG. 11B) is stopped will be given. In such a case, the control circuit controls the three driven power units 68 such that a potential difference is induced across the busbar 66A and the busbar 66B. Accordingly, an electric current illustrated by the arrow EC-2 in FIG. 11B flows. As for the current value when three power units 68 are driven, the controller may control the three driven power units 68 such that an electrical current amounting to four-thirds of the electric current when the four power units 68 are driven may be distributed. In other words, with the above control, electric power may be distributed to each of the four liquid-cooled substrates 20 in an equal manner without any problem.

As illustrated in FIG. 1, the busbars 66A and 66B are disposed in the width direction in plan view and are formed with a linear shape. Accordingly, compared with busbars 66A and 66B that have a nonlinear shape (bent shape) in plan view, the electric power supply path from the power units 68 to each of the electric terminals 67A and 67B is short.

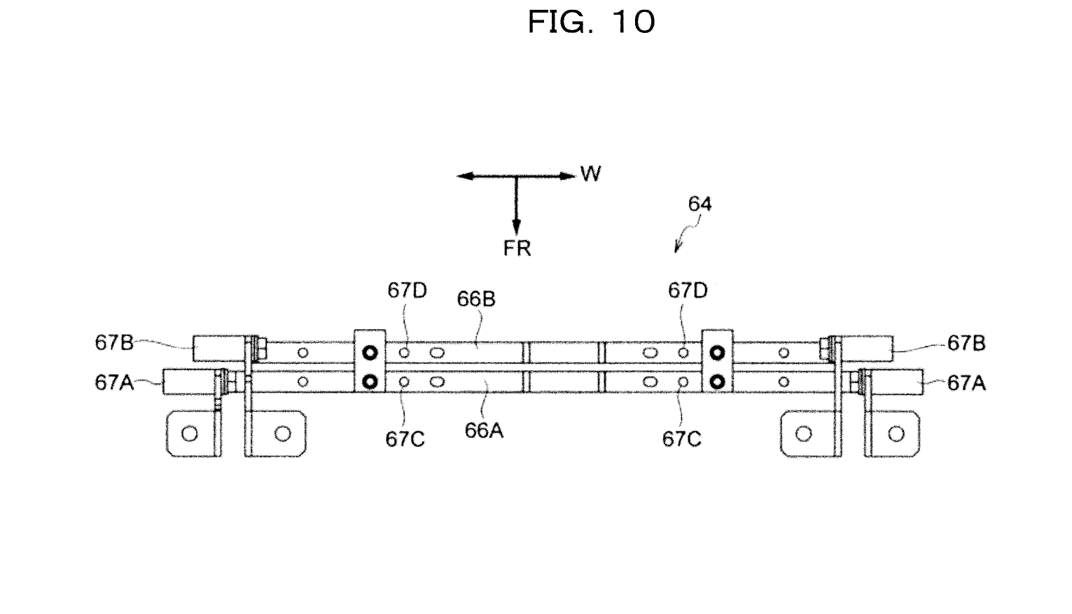

Furthermore, as illustrated in FIG. 10, electric terminals 67C and 67D for supplying electric power to the air-cooled substrate 18 are provided in the busbars 66A and 66B. Electric power may also be supplied to the air-cooled substrate 18 with the electric terminals 67C and 67D.

As illustrated in FIG. 1, two power units 68 are disposed at the left and right of the narrow-width portion 18A of the air-cooled substrate 18 in plan view. When seen in the direction of the airflow, the power units 68 do not overlap the fans 36. Accordingly, compared with a structure in which the power units 68 overlap the fans 36 in the direction of the airflow, the resistance applied by the power units 68 on the airflow is small.

In the exemplary embodiment, the air-cooled substrate 18 and the liquid-cooled substrates 20 are set apart from one another in plan view. As illustrated in FIG. 7, in the exemplary embodiment, an area A1 of the air-cooled substrate 18 on which the card connectors 24 and the air-cooled components 30 are mounted is an air-cooled area where the mounted components are cooled by air. Conversely, an area A2 above and below the liquid-cooled substrates 20 in which the refrigerant supply members are disposed is a liquid-cooled area where the mounted components are cooled by liquid. In other words, in the exemplary embodiment, the air-cooled area and the liquid-cooled area are set apart from one another in plan view.

In particular, in the exemplary embodiment, the air-cooled area (the area A1) is positioned on the front side (the near side) of the housing 16. The liquid-cooled area (the area A2) is positioned on the rear side (the far side) of the housing 16. Moreover, the liquid-cooled area (the area A2) is positioned downstream of the airflow.

As understood from FIG. 7A, in the exemplary embodiment, the air-cooled area (the area A1) is positioned upstream of the airflow with respect to the fans 36 and is positioned in the middle of the electronic device 12 in the width direction. The air-cooled components are disposed in the air-cooled area in an integrated manner. Moreover, areas A3 positioned at the left and right of the air-cooled area (the area A1) in the width direction are power unit areas where power units 68 are disposed. Furthermore, area A4 between each of the air-cooled area (the area A1) and the power unit areas (the areas A3), and the liquid-cooled area (the area A2) is a fan area where fans 36 are disposed. Note that, in the example illustrated in FIG. 7A, the busbar unit 64 is further provided in the power unit areas.

Note that the positions of the air-cooled area and the power unit areas may be changed, for example, such that the areas A3 are air-cooled areas and the area A1 is a power unit area. Furthermore, by disposing an air-cooled component in a portion of the fan area, the area A4 may be an air-cooled area. In other words, the air-cooled area may be set so as to include at least a portion of or all of the areas A1, A3, and A4. Furthermore, the area A2 (areas A5) may be set as an air-cooled area, and the areas A1, A3, and A4 may be set as liquid-cooled areas, for example.

Furthermore, the liquid-cooled area (the area A2) includes the introduction pipes 46, the discharge pipes 48, the branched introduction pipes 50, the branched discharge pipes 52, the liquid-cooled plates 44, and the air discharge ports 38 that are included in the air-cooled substrates 20.

Furthermore, the introduction pipes 46 and the discharge pipes 48 each include a portion that is disposed in the direction of the airflow, and the liquid-cooled plates 44 are positioned between the introduction pipes 46 and discharge pipes 48 in plan view. The branched introduction pipes 50 and the branched discharge pipes 52 are positioned above the liquid-cooled plates 44. A portion of each branched introduction pipe 50 and a portion of each branched discharge pipe 52 are formed in a substantially U-shape in plan view. In particular, the liquid-cooled area includes portions (gaps G1) through which the air passes; accordingly, air may be discharged from the air discharge ports 38 in a smooth manner.

In particular, in the exemplary embodiment, the intermediate substrate 22 is disposed in the liquid-cooled area. The intermediate substrate 22 connects the plurality of liquid-cooled substrates 20 to one another such that transmission and reception of signals between the liquid-cooled substrates 20 may be carried out. In the exemplary embodiment, the intermediate substrate 22 is disposed in the direction of the airflow, in other words, the intermediate substrate 22 is disposed perpendicular to the plurality of liquid-cooled substrates 20 so as to function as a duct that controls the airflow and that guides the air towards the air discharge ports 38.

In particular, in the exemplary embodiment, the area A2 includes the areas A5 where gaps G2 are formed above and below the plurality of liquid-cooled substrates 20, the gaps being formed between the plurality of liquid-cooled substrates 20 and between the liquid-cooled substrates 20 and the cover plates 76. The air (the discharged air F2) flows through the areas A5.

A function of the exemplary embodiment will be described next.

In the exemplary embodiment, the air-cooled substrate 18 and the liquid-cooled substrates 20 are set apart from one another in plan view. The air-cooled area (the area A1 illustrated in FIG. 7A) of the air-cooled substrate 18 on which components (air-cooled components) are mounted and the liquid-cooled area (the area A2 illustrated in FIG. 7A) of the liquid-cooled substrates 20 on which components (liquid-cooled components) are mounted are set apart from each other in plan view as well.

Accordingly, in the exemplary embodiment, a structure may be adopted in which members that carry out cooling with a liquid, for example, cooling water pipes, are not provided (or reduced in number) in the air-cooled area. Since members that carry out cooling with a liquid are not disposed in the air-cooled area, compared with a structure in which members for carrying out cooling with a liquid are provided in the air-cooled area A1 (the area A1), the resistance met by the air flow is small. Furthermore, turbulence of air caused by the members for carrying out cooling with a liquid may be suppressed in the air-cooled area (the area A1). Accordingly, the efficiency in cooling the air-cooled components 30 is improved.

Moreover, since the air-cooled components are disposed in the air-cooled area in an integrated manner, compared with a structure in which the air-cooled components are disposed in a dispersed manner, the area in which the airflow for cooling is generated may be narrow. Accordingly, the fans 36 may be reduced in size and, further, the electronic device 12 may be reduced in size.

Furthermore, the size of the fans 36 that cool the air-cooled components 30 with air may be reduced and the number of fans 36 may be reduced. Moreover, by reducing the size of the fans 36 or the number of fans 36, the space occupied by the fans 36 inside the housing 16 becomes small; accordingly, various members in the electronic device 12 may be disposed in a highly dense manner.

Furthermore, in the exemplary embodiment, a structure in which members, such as heat sinks and ducts, that carry out cooling with air are not provided (or are reduced in number) in the liquid-cooled area may be adopted. By not disposing any member that cools with air in the liquid-cooled area, the efficiency in which the liquid-cooled components 40 are cooled may be increased and, further, the liquid-cooled components 40 may be mounted in the liquid-cooled area in a highly dense manner. Since the refrigerant supply member 43 does not have to avoid the members that carry out cooling with air when being disposed in the liquid-cooled area, a contribution to size and weight reduction of the refrigerant supply member 43 may be made.

Moreover, in the exemplary embodiment, the air-cooled components 30, the liquid-cooled components 40, and other components are disposed in a highly dense manner in the electronic device 12; accordingly, the length of the wires between the components may be reduced and signals may be transmitted in a short time.

The exemplary embodiment is provided with fans 36. Even with a structure without the fans 36, such as a structure in which a blower that is shared by a plurality of electronic devices 12 is provided inside the housing 16, the air from the blower may be made to act on the air-cooled area. When the fans 36 are provided as in the exemplary embodiment, air may be made to act locally on the air-cooled area, thus, little blowing capacity is wasted. Moreover, an external fan of the electronic device 12 may be dispensed of or may be reduced in size.

In the exemplary embodiment, the fans 36 are provided on the air-cooled substrate 18. The fans 36 are provided at a position that is closer to the air-cooled substrate 18 than the liquid-cooled substrates 20. Since the flow of air may be generated near the air-cooled components 30, compared with a structure in which the fans 36 are provided on the other side of the air-cooled substrate 18 when viewed from the liquid-cooled substrate 20, the cooling efficiency is high.

The exemplary embodiment is provided with the power supply member 61. In an electronic device with no power supply member 61, electric power is supplied thereto from an external power source; however, in the exemplary embodiment, members such as, for example, a power cable, a power connector, and the like, for receiving electric power supplied from an external power source do not have to be provided.

In the exemplary embodiment, the power supply member 61 includes the power units 68 and the busbar unit 64. In other words, electric power is supplied to the air-cooled substrate 18 and the liquid-cooled substrates 20 from the power units 68 through the busbar units 64; accordingly, the degree of freedom of arranging the power units 68 is high. For example, in the example illustrated in FIG. 1, the power units 68 are arranged at the left and right of the connection cards 26 in the width direction of the electronic device 12; however, other arrangements are possible and an effective layout may be adopted in the housing 16.

Moreover, the power supply paths from the power units 68 to the air-cooled substrate 18 and to the liquid-cooled substrates 20 may be shortened such that drop of voltage may be averted.

The power units 68 are disposed at positions avoiding the air-cooled area, in other words, the power units 68 are disposed at positions avoiding the air passage. Since the resistance applied by the power units 68 to the airflow becomes small, the air-cooled components 30 may be efficiently cooled by air.

In the exemplary embodiment, the power unit 68 is provided in a plural number. Moreover, the plurality of power units 68 is electrically connected to the liquid-cooled substrates 20 with the busbar unit 64. Accordingly, even if one or some of the plurality of power units 68 are in a stopped state, electric power may be supplied to the liquid-cooled substrates 20 by driving the remaining one or some of the plurality of power units 68.

In the exemplary embodiment, the connection cards 26 are provided on the air-cooled substrate 18. By using the connection cards 26, external devices may be connected to the electronic device 12.

The connection cards 26 are provided on the air-cooled substrate 18 on the side of the air-cooled substrate 18 opposite the liquid-cooled substrates 20. Accordingly, compared with a structure in which the connection cards 26 are provided on the air-cooled substrate 18 on the liquid-cooled substrates 20 side of the air-cooled substrate 18, when connecting external devices to the connection cards 26, connection work is carried out easily since the liquid-cooled substrates 20 will not be in the way.

In particular, in the exemplary embodiment, since the connection ports 28 face the front direction (the direction opposite to the liquid-cooled substrate 20), compared with a structure in which the connection ports 28 face the rear direction, work in connecting the connection ports 28 to external devices is carried out easily.

Furthermore, when replacing or inspecting a component on the air-cooled substrate 18 while continuously operating the electronic device 12, since the air-cooled substrate 18 is positioned on the front side of the electronic device 12, it is easy to carry out the replacement or inspection work.

In the exemplary embodiment, the power units 68 are also provided inside the housing 16 and on the front side of the electronic device 12. Accordingly, it is easy to replace or inspect the power units 68 while the electronic device 12 is continuously operated.

In the exemplary embodiment, the refrigerant supply member 43 includes the introduction pipe 46, the branched introduction pipes 50, the branched discharge pipes 52, and the discharge pipe 48, and gaps G1 (see FIG. 8) are formed between the liquid-cooled plates 44, and portions of the branched introduction pipes 50 and portions of the branched discharge pipes 52. Compared with a structure without any gap G1, air may flow in a smooth manner through the gaps G1 and efficiency in cooling the air-cooled components 30 is high.

In the exemplary embodiment, the plurality of liquid-cooled substrates 20 is electrically connected to one another with the intermediate substrate 22. In other words, the plurality of liquid-cooled substrates 20 may be electrically connected to one another through the intermediate substrate 22.

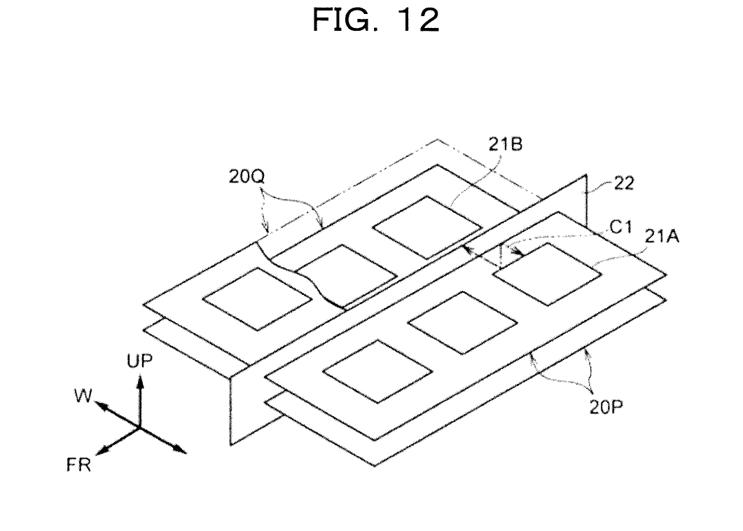

In particular, in the exemplary embodiment, as illustrated in FIG. 12, the intermediate substrate 22 is disposed between groups of two liquid-cooled substrates 20 that are disposed in the width direction such that the left and right liquid-cooled substrates 20 arranged in the width direction are connected to the intermediate substrate 22. In other words, the liquid-cooled substrates 20 are separated into two groups in the width direction and the intermediate substrate 22 is disposed between the separated groups of two liquid-cooled substrates 20.

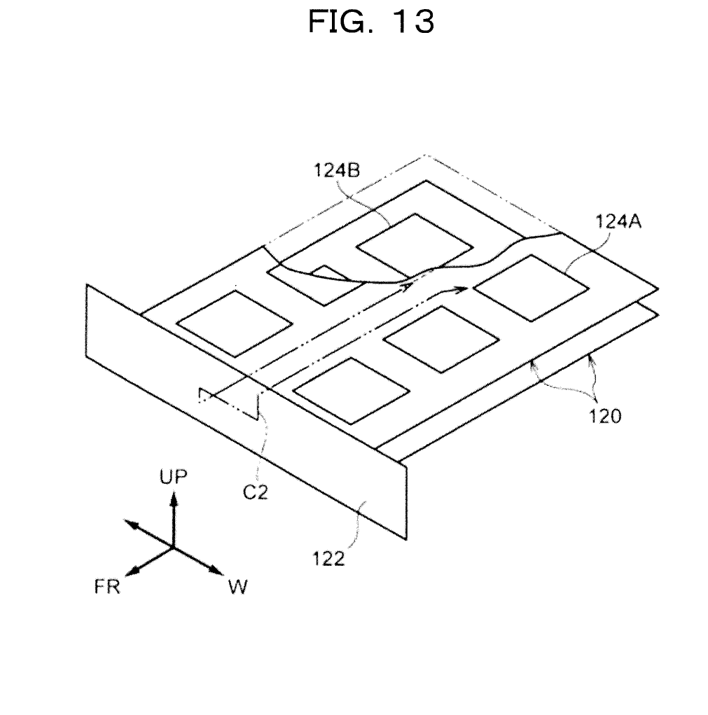

As in a comparative example illustrated in FIG. 13, a structure may be conceived in which two liquid-cooled substrates 120, each of which is not separated in the width direction and is an integrated body of the liquid-cooled substrates, may be disposed one on top of the other, and the liquid-cooled substrates 120 disposed one on top of the other may be electrically connected with a connection substrate 122 on the front side (or on the rear side). However, in the structure of the comparative example, since a connection path C2 of a cooled component 124A on the rear side of the liquid-cooled substrate 120A on the upper side and a component 124B on the rear side of the liquid-cooled substrate 120B on the lower side passes through the connection substrate 122 on the front side, for example, the connection path C2 is long.

Conversely, in the exemplary embodiment, since a connection path C1 of a component 21A on the rear side of the liquid-cooled substrate 20P on the upper side and a component 21B on the rear side of the liquid-cooled substrate 20Q on the lower side passes through the intermediate substrate 22 disposed in the middle in the width direction, the length of the connection path C1 is shorter than the length of the connection path C2 of the structure of the comparative example. Note that the components 21A and 21B may be cooled components; however, they do not have to be cooled components.

Moreover, in the exemplary embodiment, since the liquid-cooled components 40 of a liquid-cooled substrate 20 and the liquid-cooled components 40 of another liquid-cooled substrate 20 are connected through the intermediate substrate 22, the connection distances between the liquid-cooled components 40 become nearly the same resulting in suppression of excessively long connection paths.

In the exemplary embodiment, the intermediate substrate 22 is disposed in the direction of the airflow. Accordingly, compared with a structure in which the intermediate substrate 22 is disposed in an oblique manner with respect to the direction of the airflow, for example, a smooth airflow may be created since the intermediate substrate 22 does not impede the airflow.

The intermediate substrate 22 not only connects the plurality of liquid-cooled substrates 20 to one another, but also connects the air-cooled substrate 18 to the plurality of liquid-cooled substrates 20. Accordingly, a member that connects the liquid-cooled substrates 20 and the air-cooled substrate 18 to one another is not called for and the structure of the electronic device 12 may be simplified.

Viewing in the direction of the airflow, the intermediate substrate 22 is disposed perpendicular to the air-cooled substrate 18. Accordingly, compared with a structure in which the intermediate substrate 22 is disposed parallel to the air-cooled substrate 18, unintentional mixing of the airflows in the left and right (both sides in the width direction) of the intermediate substrate 22 is suppressed and smooth airflows may be created.

The plurality of liquid-cooled substrates 20 are each positioned on the left or right of the intermediate substrate 22. In the example illustrated in FIG. 9, the four liquid-cooled substrates 20 are positioned such that two liquid-cooled substrates 20 are disposed on each side of the intermediate substrate 22. In other words, the intermediate substrate 22 is positioned in the middle of the liquid-cooled substrates 20 in the width direction. Accordingly, compared with a structure in which the intermediate substrate 22 is arranged in an uneven manner to one side in the width direction, the air is guided in a highly effective manner since the air is guided in a further even manner through both the left and right sides in the width direction.

The connection connectors 62 are provided on both sides of the intermediate substrate 22. Accordingly, the liquid-cooled substrates 20 may be readily connected to either side of the intermediate substrate 22.

When viewed in a direction normal to the intermediate substrate 22, the connection connectors 62 of the intermediate substrate 22 on one surface of the intermediate substrate 22 and those on the other surface of the intermediate substrate 22 are provided at different positions. When the liquid-cooled substrates 20 on one side of the intermediate substrate 22 in the width direction and the liquid-cooled substrates 20 on the other side of the intermediate substrate 22 in the width direction are connected at inverted positions with respect to one another, even if the heights of the signal connectors 60 of the liquid-cooled substrate 20 are different, by corresponding to the difference in the height of the signal connectors 60, the liquid-cooled substrates 20 may be connected to the intermediate substrate 22 so that the liquid-cooled substrates 20 are arranged at the same height on both sides of the intermediate substrate 22.

Note that, in the above description, the “air-cooled component” and the “the liquid-cooled component” may be distinguished by, for example, the cooling capacity called for or the shape of the component. Even if referring to the same component, there may be cases in which when mounted on the air-cooled substrate 18, the component is referred to as an “air-cooled component” and when mounted on the liquid-cooled substrate 20, the component is referred to as a “liquid-cooled component”. In a single electronic device 12 that has a structure having more liquid-cooling capacity than the air-cooling capacity, when a specific component is to be cooled by a relatively high cooling capacity, the component may be mounted on the liquid-cooled substrate 20 as a “liquid-cooled component”. Moreover, a component sufficiently cooled by the cooling capacity when cooling with air may be mounted on the air-cooled substrate 18 as an “air-cooled component”.

In the exemplary embodiment described above, an example is given in which the airflow generated by the fans 36 flows in the directions of the arrows F1 and F2 illustrated in FIG. 7A, that is, an example is given in which the airflow generated by the fans 36 flows from the air-cooled substrate 18 side towards the liquid substrate 20 side; however, the direction of the airflow may be opposite to the above.

Furthermore, since the liquid-cooled components 40 on the liquid-cooled substrates 20 are cooled by liquid, air does not have to flow along the liquid-cooled substrate. Accordingly, one or some of the liquid-cooled components 40 on the liquid-cooled substrates 20 may be disposed outside the range of the airflow. Furthermore, one or some of the liquid-cooled substrates 20 may be disposed outside the range of the airflow. In such a case, there may be no gaps G1 (see FIG. 8).

The electronic device 12 of the exemplary embodiment described above is not limited to any particular device; however, server devices and large computers, for example, may be cited as the electronic device 12.

A structure in which the air-cooled substrate 18 and the liquid-cooled substrates 20 are different bodies is described above; however, for example, the structure may be an integrated substrate on which a specific area serves as an air-cooled area and a specific area other than the air-cooled area serves as a liquid-cooled area, the air-cooled components and the liquid-cooled components being mounted on the air-cooled area and the liquid-cooled area, respectively. On the integral substrate with the above structure, the area on which the air-cooled components are mounted is the air-cooled substrate and the area on which the liquid-cooled components are mounted is the liquid-cooled substrate; accordingly, a structure in which the air-cooled substrate and the liquid-cooled substrate are set apart from each other on a plane is realized.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An electronic device comprising:
an air-cooled substrate on which an air-cooled component that is cooled by an airflow is mounted;
a liquid-cooled substrate that is set apart from the air-cooled substrate in plan view, the liquid-cooled substrate being mounted thereon a liquid-cooled component that is cooled by a liquid; and
a refrigerant supply member that is disposed above the liquid-cooled substrate, the refrigerant supply member supplying a refrigerant that cools the liquid-cooled component.

2. The electronic device according to claim 1, further comprising
a fan that generates an airflow that cools the air-cooled component.

3. The electronic device according to claim 2, wherein
the fan is provided more to an air-cooled substrate side than the liquid-cooled substrate.

4. The electronic device according to claim 1, further comprising
a power supply member that supplies electric power to the air-cooled substrate and the liquid-cooled substrate.

5. The electronic device according to claim 4, wherein
the power supply member includes
a power unit that generates electric power, and
an electric connection member that electrically couples the power unit and the liquid-cooled substrate to each other.

6. The electronic device according to claim 5, wherein
the power unit is provided more to the air-cooled substrate side than the liquid-cooled substrate at a position avoiding a passage of an airflow.

7. The electronic device according to claim 6, further comprising
a plurality of the power units, wherein
the electric connection member electrically connects the plurality of the power units and the liquid-cooled substrate to one another.

8. The electronic device according to claim 1, wherein
the air-cooled substrate is provided with a connection member that connects an external device.

9. The electronic device according to claim 8, wherein
the connection member is provided on the air-cooled substrate at a portion that is on a side opposite to the liquid-cooled substrate.

10. The electronic device according to claim 1, wherein
the refrigerant supply member forms an air passage that is a passage of the airflow.

11. The electronic device according to claim 1, further comprising
a plurality of the liquid-cooled substrates, and
a connection substrate that connects the plurality of the liquid-cooled substrates to one another.

12. The electronic device according to claim 11, wherein
the connection substrate is disposed in a flow direction of the airflow.

13. The electronic device according to claim 11, wherein
the connection substrate is connected to the air-cooled substrate.

14. The electronic device according to claim 13, wherein
the connection substrate is disposed perpendicular to the air-cooled substrate when viewed in the flow direction of the airflow.

15. The electronic device according to claim 14, wherein
the plurality of the liquid-cooled substrates are arranged on both sides of the connection substrate.

16. The electronic device according to claim 15, wherein
connection connectors to which the liquid-cooled substrates are connected are provided on both surfaces of the connection substrate.

17. The electronic device according to claim 16, wherein
a liquid-cooled substrate on one side that is connected to one surface of the connection substrate is connected to the connection substrate at an inverted position with respect to a position of a liquid-cooled substrate on the other side that is connected to the other surface of the connection substrate, and
a connection connector on the one surface is provided at a position different to the position of a connection connector on the other surface when viewed in a direction normal to the connection substrate.
